(19) United States
(12) Patent Application Publication
(10) Pub. No.: US 2005/0258534 A1
(43) Pub. Date: Nov. 24, 2005

(54) Arrangement for receiving an electronic component capable of high power operation

(75) Inventors: Takeshi Hanawa, Tokyo-to (JP); Kenichi Hashizume, Yoshioka Town (JP)

Correspondence Address: HARRINGTON & SMITH, LLP, 4 RESEARCH DRIVE, SHELTON, CT, 06484-6212, US

(73) Assignee: Nokia Corporation

(21) Appl. No.: 10/852,314

(22) Filed: May 24, 2004

(51) Int. Cl. H01L 23/34; H01L 21/48

(52) U.S. Cl. 257/713; 438/125; 257/720

(57) ABSTRACT

An arrangement, for receiving an electronic component capable of high power operation, comprising: an organic substrate comprising an upper surface, a lower surface and an aperture extending through the organic substrate between the upper surface and the lower surface; and a conductor, located within the aperture of the organic substrate, having a width and a depth, for coupling to the electronic component and for transferring thermal energy from the electronic component through the organic substrate, wherein the width of the conductor is greater than the depth of the conductor.

### FIELD OF THE INVENTION

Embodiments of the present invention relate to an arrangement for receiving an electronic component capable of high power operation.

### BACKGROUND TO THE INVENTION

Electronic components which operate at high power (for example, power amplifier components such as RF modules) are typically mounted on ceramic substrates using surface mount technology. The ceramic substrates are then placed on a base substrate (for example, a printed wiring board) so that they may be electrically connected to one another. During operation, electronic components generate thermal energy which must be transferred away or else the electronic component may overheat and become damaged. Thermal energy may be transferred from electronic components to the base substrate through thermal via holes that extend through the ceramic substrate.

Ceramic substrates usually comprise a plurality of different materials which contract after the substrate has been fired at high temperature. This contraction makes ceramic substrates difficult to design and manufacture and consequently, they are usually relatively expensive to manufacture and have a limited number of designs.

It is desirable to provide an alternative for mounting electronic components which operate at high power.

### BRIEF DESCRIPTION OF THE INVENTION

According to one aspect of the present invention there is provided an arrangement, for receiving an electronic component capable of high power operation, comprising: an organic substrate comprising an upper surface, a lower surface and an aperture extending through the organic substrate between the upper surface and the lower surface; and a conductor, located within the aperture of the organic substrate, having a width and a depth, for coupling to the electronic component and for transferring thermal energy from the electronic component through the organic substrate, wherein the width of the conductor is greater than the depth of the conductor.

One advantage provided by embodiments of the present invention is that organic substrates are relatively cheap to design and manufacture. This is because an organic substrate may be injection moulded or formed by a plurality of laminate sheets under low temperatures. These manufacturing processes are well known and consequently, the cost associated with organic substrates may be less than that associated with ceramic substrates. Organic substrates usually have low thermal conductance which may cause overheating of an electronic component if it is operating at high power. The conductor helps to prevent the electronic component from overheating and becoming damaged.

The width of the conductor may be constant throughout its depth. The conductor may be directly coupled to the electronic component. The electronic component may comprise a first surface area and the conductor may comprise a second surface area, for coupling to the first surface area of the electronic component, the first surface area and the second surface area may be substantially the same size.

It is necessary to design the conductor so that it is proportioned to transfer sufficient thermal energy from the electronic component to help prevent overheating and damage during operation.

The organic substrate may be coupled to a base substrate. The conductor may be coupled to the base substrate to transfer thermal energy from the electronic component to the base substrate. The conductor may be coupled to the base substrate to provide an electrical ground for the electronic component.

The electronic component may be an integrated circuit (IC). The organic substrate may comprise liquid crystal polymer (LCP), poly tetrafluoro ethylene (Teflon) or poly benzo cyclo butene (BCB). The conductor may comprise copper or tungsten.

One advantage associated with using LCP, Teflon and BCB is that they have relatively low dielectric loss and low dielectric constants when compared with other organic materials. Therefore, these materials do not heat up as much as other organic materials when placed in an alternating electric field. Additionally, they are relatively durable under high temperature conditions. Consequently, these materials provide a suitable substrate on which to mount an integrated circuit because they have good electrical and mechanical properties.

According to a further aspect of the present invention there is provided a method of manufacturing an arrangement for receiving an electronic component capable of high power operation, comprising: providing an organic substrate comprising an upper surface, a lower surface and an aperture extending through the organic substrate between the upper surface and the lower surface; and providing a conductor within the aperture of the organic substrate, having a width and a depth, for coupling to the electronic component and for transferring thermal energy from the electronic component through the organic substrate, wherein the width of the conductor is greater than the depth of the conductor.

According to another aspect of the present invention there is provided an arrangement, for receiving an electronic component capable of high power operation and having a first surface area, comprising: an organic substrate comprising an upper surface, a lower surface and an aperture extending between the upper surface and the lower surface; and a conductor, having a second surface area for coupling to the first surface area of the electronic component, located within the aperture of the organic substrate, for transferring thermal energy from the electronic component through the organic substrate, wherein the first area of the electronic component and the second area of the conductor are of substantially the same size.

### BRIEF DESCRIPTION OF THE DRAWINGS

For a better understanding of the present invention reference will now be made by way of example only to the accompanying drawings in which:

FIG. 1 illustrates a schematic diagram of one embodiment of the present invention;

FIG. 2 illustrates a schematic diagram of the embodiment illustrated in FIG. 1 arranged for operation.

### DETAILED DESCRIPTION OF EMBODIMENTS OF THE INVENTION

The figures illustrate an arrangement 10, for receiving an electronic component 12 capable of high power operation, comprising: an organic substrate 14 comprising an upper surface 20, a lower surface 22 and an aperture 18 extending through the organic substrate 14 between the upper surface 20 and the lower surface 22; and a conductor 16, located within the aperture 18 of the organic substrate 14, having a width (w) and a depth (d), for coupling to the electronic component 12 and for transferring thermal energy from the electronic component 12 through the organic substrate 14, wherein the width (w) of the conductor 16 is greater than the depth (d) of the conductor 16.

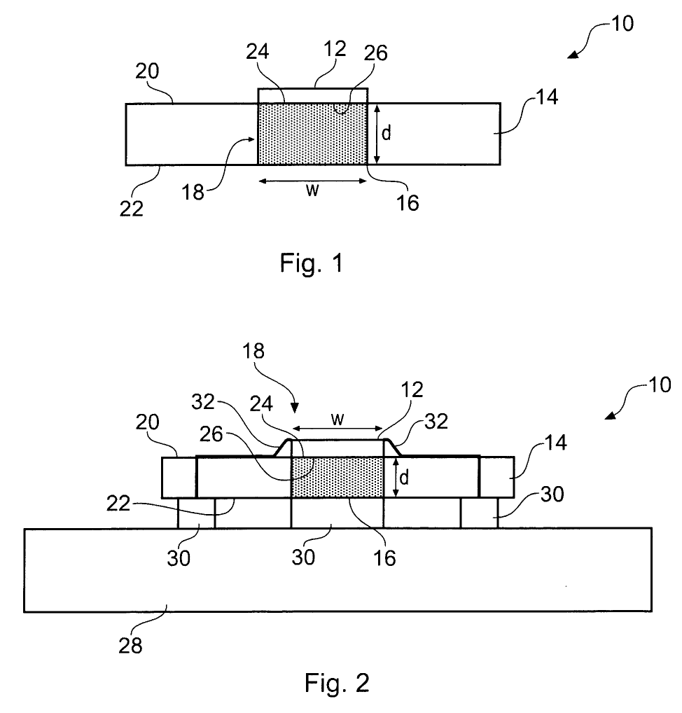

FIG. 1 illustrates an arrangement 10 for receiving an electronic component 12 capable of high power operation and having a first surface area 24. In this example, the electronic component 12 is an integrated circuit (IC). The IC 12 is received by an organic substrate 14 and in operation, thermal energy is transferred from the IC 12 to a conductor 16, located within the organic substrate 14, thereby helping to prevent the IC 12 from overheating and becoming damaged.

The arrangement may be used for any high speed digital application, for example, it may be used for a high speed CPU. The arrangement may be used for a radio frequency (RF) module for a power amplifier.

The organic substrate 14 comprises an aperture 18 that extends through the organic substrate 14 between an upper surface 20 and a lower surface 22 of the organic substrate 14. The conductor 16 is located within the aperture 18 and in this example, extends between the upper surface 20 and the lower surface 22 of the organic substrate 14. The conductor 16 is placed within the aperture 18 using surface mount technology. Surface mount technology is well known in the art of electronic engineering and is therefore not described in detail. The organic substrate comprises, in this example, liquid crystal polymer (LCP). Alternatively, it may comprise poly tetrafluoro ethylene (Teflon) or poly benzo cyclo butene (BCB).

One advantage associated with LCP, Teflon and BCB is that they have low dielectric loss and low dielectric constants. Consequently, these materials do not heat up as much as other organic materials when placed in an alternating electric field. Additionally, they are also relatively durable under high temperatures. Consequently, these materials provide a suitable substrate on which to mount an integrated circuit because they have good electrical and mechanical properties.

The conductor 16 conducts thermal energy from the IC 12 and in this example, comprises metal. Any suitable metal may be used which has high thermal conductivity and may, for example, comprise copper or tungsten. The conductor 16 is proportioned such that, in use, there is sufficient transfer of thermal energy from the IC 12 to the conductor 16 so as to help prevent the IC 12 from overheating. In this example, the width (w) of the conductor 16 is greater than the depth (d) of the conductor 16 and the first surface area 24 of the IC 12 is substantially the same as a second surface area 26 of the conductor 16. Additionally, in this example, the first surface area 24 of the IC 12 is directly coupled to the second surface area 26 of the conductor 16.

FIG. 2 illustrates the arrangement 10 of FIG. 1 arranged for operation. The reference numerals used in FIG. 2 are the same as those used in FIG. 1 for features that have been illustrated in FIG. 1. In this example, the organic substrate 14 is coupled to a base substrate 28 via solder 30. The base substrate 28 is, in this example, an organic printed wiring board (PWB) and may receive a plurality of organic and non organic substrates. The IC 12 is electrically coupled to the base substrate 28 via electrodes 32. The electrodes 32 extend through the organic substrate 14 and are coupled to solder 30. The electrodes are inserted into the organic substrate 14 using surface mount technology. The conductor 16 is coupled to the base substrate via solder 30 for reasons which will be explained in the following paragraphs.

In operation, an electrical signal is provided from an electronic component mounted on the base substrate 28 (not illustrated) to the IC 12 via solder 30 and electrodes 32. The IC 12 may process and transmit the electrical signal to a further electronic component mounted on the base substrate 28 (not illustrated). During processing, thermal energy is generated by the IC 12 and transferred to the base substrate 28 via the conductor 16 and solder 30. Consequently, the conductor 16 helps to prevent the IC 12 from overheating. Furthermore, the conductor 16 provides an electrical ground for the IC 12.

Although embodiments of the present invention have been described in the preceding paragraphs with reference to various examples, it should be appreciated that modifications to the examples given can be made without departing from the scope of the invention as claimed. For example, the organic substrate 14 may receive one or more integrated circuits. The base substrate 28 may receive more than one organic substrate 14. The base substrate 28 may comprise ceramic material. The organic substrate 14 may be integrated with the base substrate 28 to form a single substrate.

Whilst endeavouring in the foregoing specification to draw attention to those features of the invention believed to be of particular importance it should be understood that the applicant claims protection in respect of any patentable feature or combination of features hereinbefore referred to and/or shown in the drawings whether or not particular emphasis has been placed thereon.

1. An arrangement, for receiving an electronic component capable of high power operation, comprising:
an organic substrate comprising an upper surface, a lower surface and an aperture extending through the organic substrate between the upper surface and the lower surface; and
a conductor, located within the aperture of the organic substrate, having a width and a depth, for coupling to the electronic component and for transferring thermal energy from the electronic component through the organic substrate, wherein the width of the conductor is greater than the depth of the conductor.

2. An arrangement as claimed in claim 1, wherein the width (w) of the conductor is constant throughout its depth (d).

3. An arrangement as claimed in claim 1, wherein the conductor is directly coupled to the electronic component.

4. An arrangement as claimed in claim 1, wherein the electronic component comprises a first surface area and the conductor comprises a second surface area, for coupling to the first surface area of the electronic component, the first surface area and the second surface area being of substantially the same size.

5. An arrangement as claimed in claim 1, wherein the organic substrate is coupled to a base substrate.

6. An arrangement as claimed in claim 5, wherein the conductor is coupled to the base substrate to transfer thermal energy from the electronic component to the base substrate.

7. An arrangement as claimed in claim 5, wherein the conductor is coupled to the base substrate to provide an electrical ground for the electronic component.

8. An arrangement as claimed in claim 1, wherein the electronic component is an integrated circuit.

9. An arrangement as claimed in claim 1, wherein the organic substrate comprises liquid crystal polymer (LCP), poly tetrafluoro ethylene (Teflon) or poly benzo cyclo butene (BCB).

10. An arrangement as claimed in claim 1, wherein the conductor comprises copper or tungsten.

11. A method of manufacturing an arrangement for receiving an electronic component capable of high power operation, comprising:
providing an organic substrate comprising an upper surface, a lower surface and an aperture extending through the organic substrate between the upper surface and the lower surface; and
providing a conductor within the aperture of the organic substrate, having a width and a depth, for coupling to the electronic component and for transferring thermal energy from the electronic component through the organic substrate, wherein the width of the conductor is greater than the depth of the conductor.

12. An arrangement, for receiving an electronic component capable of high power operation and having a first surface area, comprising:
an organic substrate comprising an upper surface, a lower surface and an aperture extending between the upper surface and the lower surface; and
a conductor, having a second surface area for coupling to the first surface area of the electronic component, located within the aperture of the organic substrate, for transferring thermal energy from the electronic component through the organic substrate, wherein the first area of the electronic component and the second area of the conductor are of substantially the same size.
